(19) United States
(12) Patent Application Publication
(10) Pub. No.: US 2025/0210442 A1
(43) Pub. Date: Jun. 26, 2025

(54) PUMP-OUT RESISTANT COLDPLATE

(71) Applicant: Microsoft Technology Licensing, LLC, Redmond, WA (US)

(72) Inventors: Kathryn OSEEN-SENDA, Seattle, WA (US); Oscar FARIAS MOGUEL, Seattle, WA (US); Dennis TRIEU, Redmond, WA (US)

(73) Assignee: Microsoft Technology Licensing, LLC, Redmond, WA (US)

(21) Appl. No.: 18/391,416

(22) Filed: Dec. 20, 2023

(51) Int. Cl. H01L 23/367; H01L 23/00

(52) U.S. Cl. CPC H01L 23/367; H01L 24/26; H01L 24/29; H01L 24/32; H01L 2224/2612; H01L 2224/29191; H01L 2224/29193; H01L 2224/32245; H01L 2924/0715

(57) ABSTRACT

A heat exchanger comprising a heatsink and/or coldplate is disposed on a semiconductor having a heat-producing die within. A layer of thermal interface material (TIM) is disposed between the heat exchanger and semiconductor to enhance heat dissipation as the semiconductor is operated. A seal including a gasket or edgebond adhesive is provided around the perimeter edges of the heat exchanger and semiconductor to seal the gap around the periphery of the TIM layer to prevent the TIM from getting pumped out with cyclical thermal loading of the assembly. A capillary tube in the heat exchanger extending from the internal TIM layer to an opening exposed to the surrounding environment provides a reservoir to capture TIM that would otherwise be pumped out. Dimensions of the capillary tube are selected to prevent environmental air from passing by the TIM in the tube and getting entrapped in the TIM layer as voids.

### BACKGROUND

Computing devices generate heat as a byproduct of computational workloads. The heat is removed from the devices to enable processing to continue without incurring damage to constituent electronic components such as semiconductors. A heat exchanger receives heat from the electronic components to efficiently remove heat from the computing device and dissipate it to a surrounding environment.

### SUMMARY

Disclosed is a semiconductor assembly having resistance to a failure mechanism known as the “pump-out effect” in which thermal interface material (TIM) is displaced by a membrane-like pump movement of components in the assembly as the semiconductor is cyclically thermally loaded as it is operated. The semiconductor includes a heat-producing die within and is optionally configured with an integrated heat spreader that can be incorporated into a lid of the semiconductor. A heat exchanger, illustratively comprising a heatsink and/or coldplate which is optionally liquid-cooled, is located on a broad area surface of the semiconductor and TIM is utilized as a gap-filling layer between the mating surfaces of the heat exchanger and semiconductor.

In a first illustrative embodiment of the semiconductor assembly, a capillary tube disposed in the heat exchanger extends from the internal TIM layer to an opening that is exposed to the environment surrounding the assembly. The capillary tube provides a reservoir into which a viscous liquid TIM is displaced and from which the TIM is recovered as the semiconductor assembly is cyclically thermally loaded. The capillary tube is designed with a high aspect ratio, i.e., having a small diameter and a relatively long length, to prevent air from the surrounding environment intruding past the TIM in the tube and becoming entrapped within the TIM layer to form internal gaps or voids which lower the effective thermal conductivity of the TIM. The dimensions of the capillary tube may be determined in various ways. For example, the tube diameter is selected to maintain a target pressure differential across a vapor-liquid interface between the TIM and air in the tube in which the pressure differential is determined by the radius, surface tension of the liquid TIM in the capillary tube, and a contact angle between the liquid TIM and the capillary tube sidewall.

In a second illustrative embodiment of the semiconductor assembly, an edge seal is located around a peripheral seam between the heat exchanger and semiconductor to trap the TIM within the gap and prevent extrusion from pump-out. The seal alternatively comprises gaskets, O-rings, knife-edge seals, or edgebond adhesives. Surfaces of either the heat exchanger or semiconductor are configurable with features to interface with the seal including slots, grooves, lips, offset edges, or textures which may enhance the seal effectiveness in some applications. In a third illustrative embodiment of the semiconductor assembly, both the capillary tube and peripheral edge seal are used with the semiconductor assembly in combination.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure.

### DESCRIPTION OF THE DRAWINGS

FIG. 1 is a schematic side view of an illustrative conventional semiconductor assembly;

FIG. 2 is schematic side view of an illustrative interface between hard surfaces of a heat exchanger and a semiconductor;

FIG. 3 is schematic side view of an illustrative interface between hard surfaces of a heat exchanger and a semiconductor in which a layer of fluidic thermal interface material (TIM) provides a thermal path between rough-surfaced solids through conduction;

FIG. 4 is schematic side view of an illustrative semiconductor assembly in an unpowered inoperative state;

FIG. 5 is schematic side view of an illustrative semiconductor assembly in a powered state undergoing thermal loading;

FIGS. 6, 7, and 8 are schematic side views of an illustrative semiconductor assembly in a powered state undergoing thermal loading in which the TIM pumps out between the heat exchanger and semiconductor to create air gaps in the TIM;

FIG. 9 is a top view of a TIM layer showing internal air gaps after multiple thermal loading cycles;

FIG. 10 is schematic side view of an illustrative semiconductor assembly in which a coldplate is arranged with a capillary tube that extends from a TIM layer to an opening that is exposed to the surrounding environment;

FIG. 11 is an enlarged view of a capillary tube through which TIM is displaced during a thermal heat cycle of the semiconductor when operating;

FIG. 12 shows dimensions of an illustrative capillary tube;

FIG. 13 is schematic side view of an illustrative semiconductor assembly in which a coldplate is arranged as an edge seal located around a perimeter seam between respective peripheral edges of the coldplate and a packaged semiconductor;

FIG. 14 is schematic side view of an illustrative semiconductor assembly in which a coldplate is arranged with an edge seal located around a perimeter seam between respective peripheral edges of the coldplate and a packaged semiconductor and the coldplate is arranged with a capillary tube; and

FIGS. 15-21 are schematic side views of different illustrative seals.

Like reference numerals indicate like elements in the drawings. Elements are not drawn to scale in the drawings.

### DETAILED DESCRIPTION

As computing semiconductors (i.e., “chips”) get to larger geometries and higher heat flux, it becomes more challenging to maintain and achieve ideal flatness and parallelism between the top of the chip and the bottom of a heat exchanger such as a heatsink or coldplate. Further challenges arise as the assembly flexes during alternating heating and cooling cycles. In effect, the semiconductor/heat exchanger assembly becomes a pump that squeezes the viscous thermal interface material (TIM) out of the sides, which causes empty voids between the two components when their surfaces revert back to their maximum spacing. This pump-out effect can cause contamination of neighboring components and result in a high thermal resistance at the interface between the semiconductor and heat exchanger. In some circumstances, the interface can lose enough TIM from pump-out to result in thermal failure of the semiconductor. Without TIM, the voids are thermally insulating and the semiconductor can no longer efficiently transfer heat to the nearby heat exchanger through the void space.

Some current solutions to TIM pump-out are directed to material properties of the TIM itself. For example, some applications utilize solid metal TIMs to prevent pump-out, other applications may benefit from materials like gels and thermally conductive adhesives that are dispensed like thermal greases but which are then at least partially cross-linked during curing. While such solutions can be effective in some application spaces, the present pump-out resistant coldplate is operable with a wide variety of TIM types to provide increased flexibility and design freedom for thermal management solutions.

Manufacturing of semiconductor assemblies (i.e., a semiconductor and heat exchanger in combination) can also be simplified using the present principles. For example, solid metal TIMs (e.g., using solder) are inherently pump-out resistant but may not be effective for some semiconductor assembly designs having extended areas. In addition, manufacturing processes and infrastructure need to be robust for high temperature processing and reworking. Curable TIM compositions may be less effectively used in a manufacturing environment due to reworking opportunities being negatively impacted.

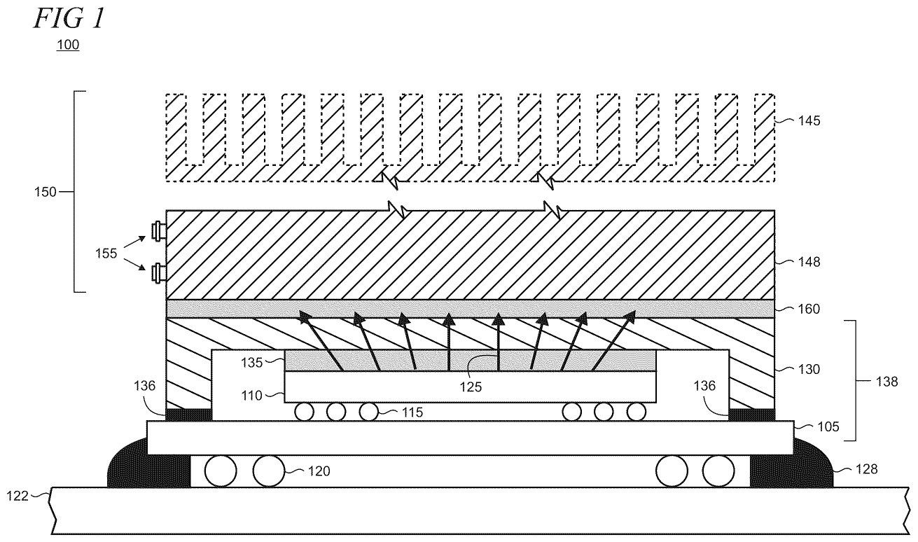

Turning now to the drawings, FIG. 1 is a schematic side view of an illustrative conventional semiconductor assembly 100. The assembly includes a substrate 105 electrically coupled to a semiconductor 110 by solder balls, representatively indicated by reference numeral 115. The use of solder balls is illustrative as the semiconductor is also connectable using other techniques such as wire bonding. Additional solder balls 120 are utilized in this illustrative example at the bottom of the substrate to attach the semiconductor assembly to a printed circuit board (PCB) 122 in an electronic device such as a computing and/or storage device. The substrate typically includes traces, pads, power/ground planes, vias, and the like to provide various electrical circuits between the PCB and semiconductor. The semiconductor may also be referred to as an integrated circuit or “chip” and internally incorporates a die (not shown) that produces heat when the semiconductor is operated.

An edge bonding feature 128, for example using an epoxy material placed around the periphery of the semiconductor 110, is used in this illustrative example to increase the mechanical strength of the bond between the semiconductor and PCB 122. Edge bonding is typically utilized in applications in which the semiconductor assembly 100 is exposed to high temperature cycling and/or environmental conditions having high levels of shock and vibration. As shown, the edge bonding feature penetrates under the substrate 105 to ensure proper mechanical bonding between the semiconductor assembly and the PCB. Edge bonding is generally removable in reworking scenarios by application of heat and mechanical scraping.

The heat produced by the semiconductor 110 (shown in the drawing by arrows 125) needs to be removed to ensure that the semiconductor assembly remains within its thermal design parameters. The semiconductor assembly optionally includes an integrated heat spreader (IHS) 130 implemented, for example, in a lid or case configuration using metal alloys. The IHS is coated with thermally conductive metallic (e.g., copper alloy) and/or composite materials in some embodiments. TIM 135, such as a curable or other suitable composition, is typically utilized to decrease the thermal resistance of the interface between the semiconductor and the IHS.

A gasket 136 or other suitable seal around the lower periphery of the IHS is optionally utilized at the interface between the IHS and substrate 105 to encapsulate the semiconductor from the surrounding environment. Semiconductor encapsulation creates a hermetic barrier between the semiconductor circuits and the lid assembly or enclosure to protect, for example, against corrosion and electrical shorts caused by water vapor and condensation. The combination of IHS, semiconductor, and substrate is commonly referred to as a semiconductor package, as indicated by reference numeral 138.

In this illustrative example, the IHS 130 has a substantially planar broad area top surface, although non-planar or partially non-planar broad area surfaces are alternatively usable. The top surface of the IHS is configured to interface with a mating bottom surface of a heat exchanger 150. The heat exchanger is typically attached to the IHS using fasteners (not shown) such as clamps, screws, and the like to effectuate a uniform and constant contact pressure between the components which ensures effective heat transfer.

The heat exchanger comprises a heatsink or coldplate, or a combination of both. When configured as a heatsink, a number of cooling fins 145 extend from a base 148 of the heat exchanger to increase its radiant surface area. Fins are not typically used when the heat exchanger is configured as a coldplate. The selection of heatsink or coldplate is a design choice based on requirements of a specific application such as anticipated thermal loading of the semiconductor and size and weight considerations for the assembly. However, the present principles are adaptable to both heatsink and coldplate configurations. It may be appreciated that the heat output of a given semiconductor is not spatially uniform in typical applications. The cooling provided to the semiconductor by the heat exchanger is also generally non-uniform.

An exemplary coldplate arrangement incorporates liquid-cooling in which a coolant is piped through channels (not shown) of the heat exchanger 150 to and from an external liquid-cooling system using tubes or hoses that interface with inlet/outlet fluid couplers 155. The external cooling system typically includes suitable pumps, tanks, and heat exchangers to efficiently transfer thermal energy from the semiconductor assembly 100 to an external environment via the coolant as a heat transfer medium.

The heat exchanger 150 is disposed on the IHS 130. A layer of TIM 160 is utilized between the components, as shown. Various types and classes of TIM can be utilized as needed to meet the thermal conductivity and reliability requirements of a given application. For example, the TIM is selectable from phase change material, thermal grease, thermal paste, thermal putty, thermal gel, graphite-based material, silicone-based material, metal-based material, or combinations thereof. Many current TIM formulations are composites containing particulate fillers to increase thermal conductivity. Inorganic particulate fillers include aluminum oxide, magnesium oxide, aluminum nitride, boron nitride, and diamond powder. Metal fillers, notably silver, are also usable in some cases.

In addition to thermal performance, TIMs are selected based on other criteria including, for example, ease of use in initial assembly and/or rework during manufacturing of the semiconductor assembly 100. TIM properties of at least partial viscosity at some temperatures may facilitate manufacturing process flows in some scenarios. TIMs may also need to be electrically isolating or provide some structural fastening of the heat exchanger to the semiconductor.

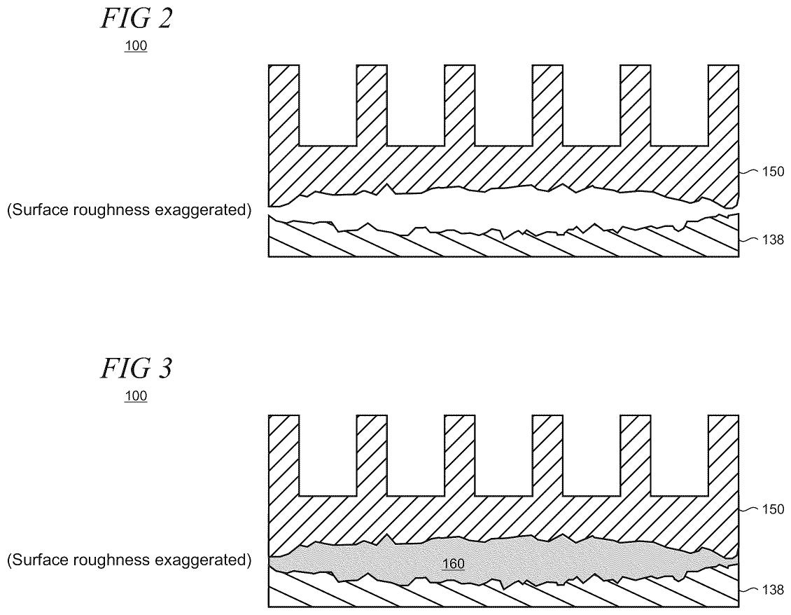

FIG. 2 is schematic side view of an illustrative interface between hard surfaces of the heat exchanger 150 and semiconductor 110. Standard machined surfaces are rough and wavy, as shown in the drawing (where the surface roughness is exaggerated for emphasis). The surface roughness typically provides for relatively few actual contact points between the heat exchanger and semiconductor. The insulating air gaps created by multiple voids of “contacting” hard surfaces are simply too large a thermal barrier for even modest power applications. The thermal barrier is overcome by eliminating air intrusion by introducing the TIM 160 to the heat path. The TIM has fluid properties to wet the surfaces of the heat exchanger and packaged semiconductor 138. As shown in FIG. 3, the TIM essentially changes the thermal path between rough-surfaced solids from conduction through point contacts and air to conduction entirely through solids.

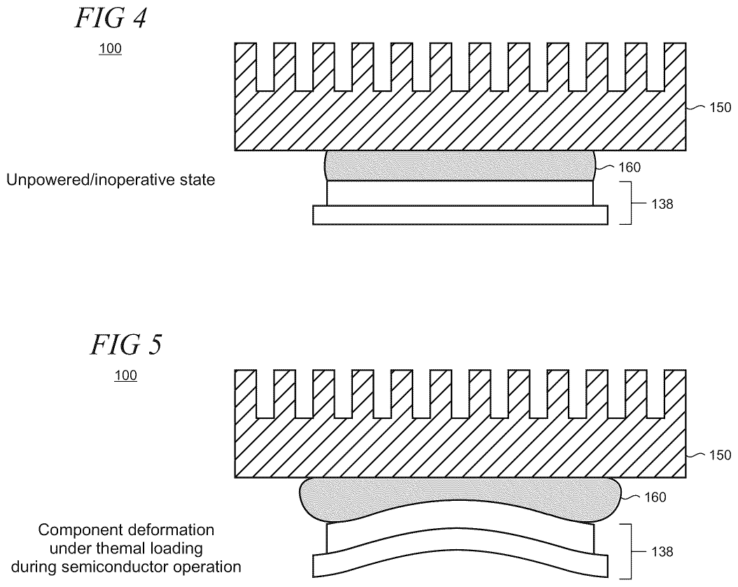

FIG. 4 is a schematic side view of the semiconductor assembly 100 in an unpowered inoperative state. As shown, the broad area mating surfaces of the heat exchanger 150 and packaged semiconductor 138 are flat and parallel to each other. The assembly is mechanically strained and undergoes recoverable deformation as the semiconductor is electrically powered and the die produces heat as a byproduct of its operation (the motions of the packaged semiconductor are exaggerated in the drawings for emphasis).

Surfaces of the semiconductor package 138 are displaced under the influence of thermal loading, as shown in FIG. 5. It is noted that the postures of the semiconductor package under thermal loading shown in the drawings are arbitrary and drawn with exaggerated features for purposes of illustration. It may be appreciated that the posture of the semiconductor package can start in an initial flat state and then go either concave up or down as the package heats up.

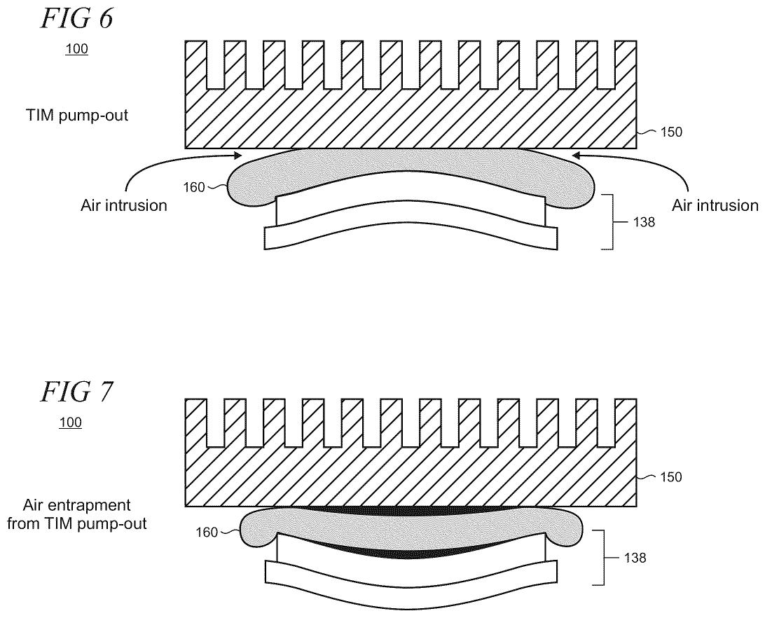

Variations in coefficients of thermal expansion among components of the semiconductor assembly can result in thermal expansion and contraction to occur at different rates. The cyclical thermal loading results in a membrane-like pumping movement of semiconductor surfaces which causes the TIM 160 to be extruded out the gaps between the heat exchanger 150 and the packaged semiconductor 138 and enables air to intrude into the opened gaps, as shown in FIG. 6, and become entrapped in the TIM, as shown in FIG. 7.

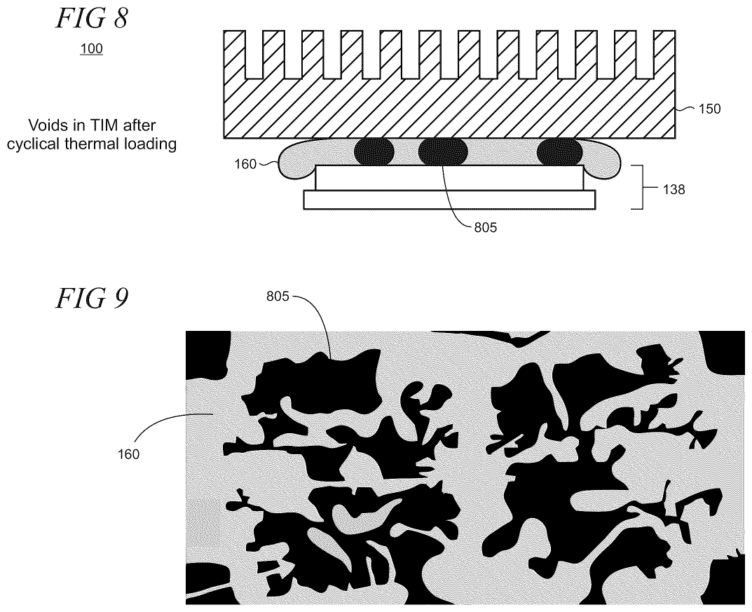

As shown in FIGS. 8 and 9, air entrapped in the TIM 160 during pump-out causes voids 805 in the TIM. The voids form a barrier in the thermal path preventing effective heat transfer from the packaged semiconductor 138 to the heat exchanger 150. As the pump-out of the TIM progresses with cyclic thermal loading, the lack of sufficient heat dissipation for the semiconductor can lead to overheating and component failure.

The pump-out effect of TIM is countered with a semiconductor assembly having mechanical design features arranged in accordance with the present principles to complement existing pump-out solutions that are directed to material properties of the TIM. The design features include a capillary tube located in the heat exchanger providing a TIM reservoir and an edge seal around the perimeter seam between the peripheral edges of the heat exchanger and semiconductor that prevents TIM extrusion during cyclical thermal loading.

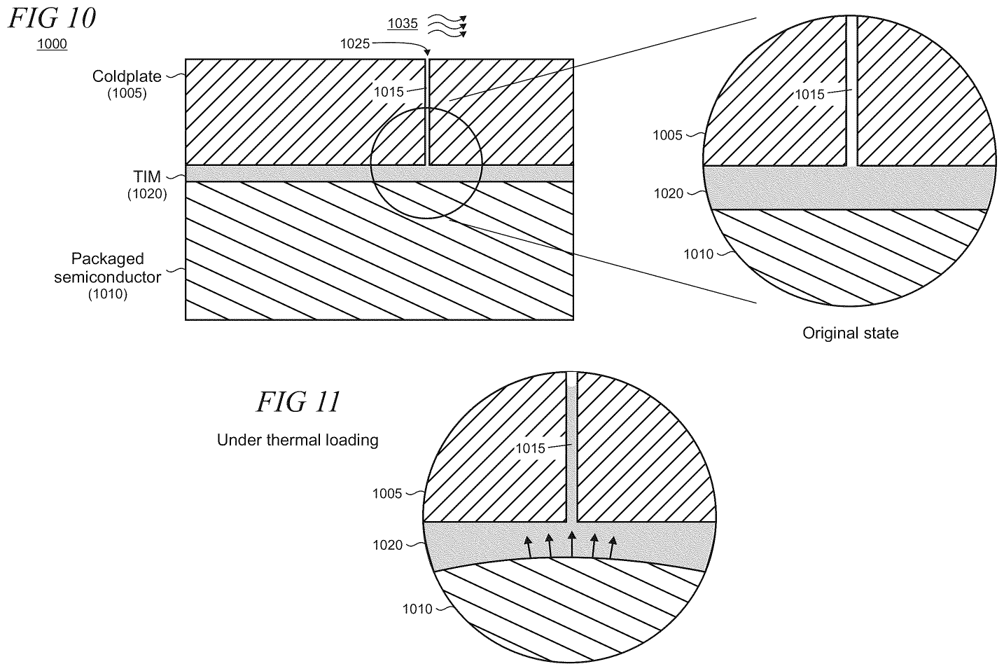

FIG. 10 is schematic side view of an illustrative semiconductor assembly 1000 in which a coldplate 1005 disposed on a packaged semiconductor 1010 is arranged with a capillary tube 1015 that extends from a layer of TIM 1020 to an opening 1025 that is exposed to the environment 1035 surrounding the assembly. The coldplate is provided in this illustrative example to disclose and highlight the present principles. The coldplate may be configured for liquid-cooling in some applications. Heatsinks are alternatively usable as appropriate to meet applicable requirements of a given thermal management application.

In an unpowered (i.e., original) state of the semiconductor assembly 1000, the opposing surfaces of the coldplate 1005 and semiconductor are substantially flat and parallel and form a thin, but broad area, volume configured to receive the TIM 1020, as shown in the enlarged view on the right side of FIG. 10. When undergoing thermal loading as the semiconductor is operated, the opposing surfaces no longer remain flat and parallel as the semiconductor surface engages in a membrane-like motion, as shown in the enlarged view in FIG. 11. The motion of the semiconductor decreases the volume of the TIM layer while increasing its pressure from the original state. As a result, the TIM is displaced and forced to travel into the capillary tube. Thermal expansion of the TIM may also cause it to be forced into the capillary tube as many materials expand when moving from solid to liquid states.

The capillary tube 1015 receives the viscous TIM as it is displaced when the semiconductor flexes with temperature changes as it operates. When the semiconductor flexes back to its original state, the TIM is sucked back into the volume formed by the gap between the coldplate 1005 and the packaged semiconductor 1010. Thus, the capillary tube functions as a reservoir into which the viscous liquid TIM is displaced and from which the TIM is recovered as the semiconductor assembly is cyclically thermally loaded.

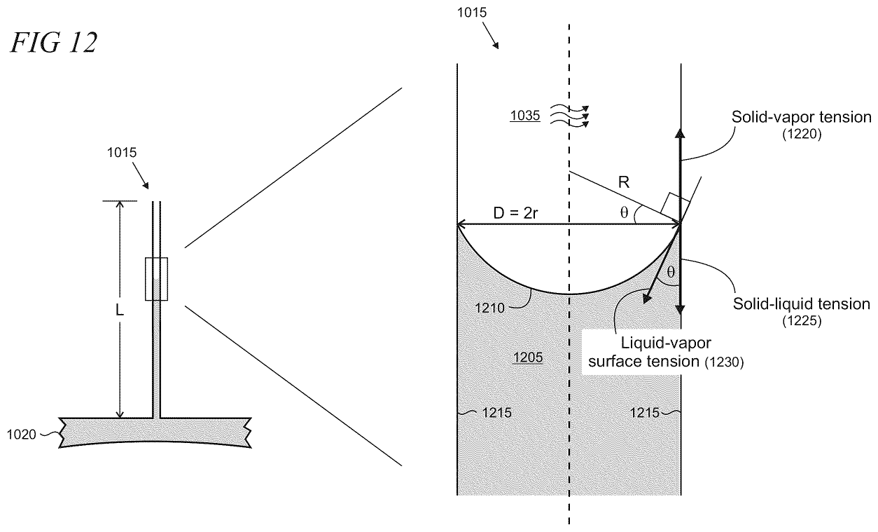

FIG. 12 shows illustrative dimensions of the capillary tube 1015 (the surrounding coldplate is not shown for clarity). The capillary tube is arranged with a high aspect ratio in which the length L is large relative to the diameter D. The comparatively long length of the capillary tube prevents air, water vapor, airborne particulates, etc. in the surrounding environment 1035 from bypassing the TIM 1205 in the capillary tube and becoming entrapped in the TIM layer 1020.

The top surface of the TIM 1205 forms a meniscus 1210 as a result of the contact angle of the TIM with the walls 1215 of the capillary tube 1015. The curvature of the meniscus is greater (i.e., the radius of curvature R is smaller) as the radius of the tube r is narrower as shown by:

$$R = \frac{r}{cos θ}$$

where θ is the contact angle. The contact angle is dependent on material properties of the TIM and capillary tube walls and may be further affected by gravity depending on the tube and coldplate orientation in some applications. The curvature causes a pressure differential to develop across the solid-liquid-vapor interfaces as shown by vectors 1220, 1225, and 1230 in the drawing.

In accordance with the present principles, the capillary tube 1015 in a given semiconductor assembly design is configured to optimize resistance against air bypassing the TIM 1205 and becoming sucked into the TIM layer at the interface between the opposing surfaces of the coldplate and semiconductor during cyclical thermal loading. The tube diameter may be selected using different methodologies. For example, the tube radius r is selected to achieve a pressure differential across the vapor-liquid interface of the static fluids (i.e., air and the viscous TIM) meeting a predetermined target value, for example 1 bar. It may be appreciated that the capillary tube dimensions, applicable material properties of the TIM, and target pressure differential may be selected to meet the needs of a particular semiconductor assembly implementation and thus can vary from what is described herein.

An alternative methodology for calculating capillary tube dimensions includes accommodating a maximum volume of TIM that can be displaced into the tube within some predetermined criteria for time interval and maximum pressure drop. It may be appreciated that this calculation methodology depends on TIM viscosity and not capillary forces within the tube.

The location of the capillary tube 1015 in the coldplate 1005 can vary and some implementations may utilize more than one capillary tube as needed to meet design requirements. A capillary tube is locatable, for example, adjacent to areas of the semiconductor of local or global maximum displacement when flexing during cyclical thermal loading. Other capillary tube locations include those adjacent to areas of the TIM 1020 and/or semiconductor having local or global maximum temperature and/or pressures.

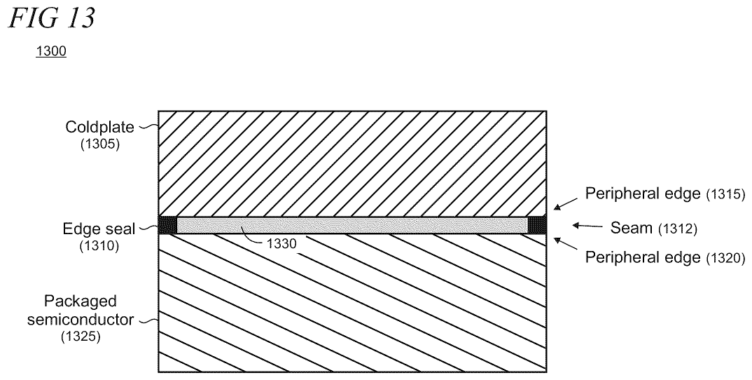

FIG. 13 is a schematic side view of an illustrative semiconductor assembly 1300 in which a coldplate 1305 is arranged with an edge seal 1310 located around a perimeter seam 1312 between respective peripheral edges 1315 and 1320 of the coldplate and a packaged semiconductor 1325. The seal is configured to trap the TIM 1330 within the thin and broad volume formed between the mating surfaces of the coldplate and semiconductor that receives a layer of TIM. The seal prevents extrusion of the TIM from the seam to prevent pump-out as the semiconductor assembly undergoes cyclical thermal loading when operated. The seal can also prevent TIM leakage in scenarios in which, for example, relatively low-viscosity materials are utilized that may otherwise leak from the semiconductor assembly simply from the force of gravity.

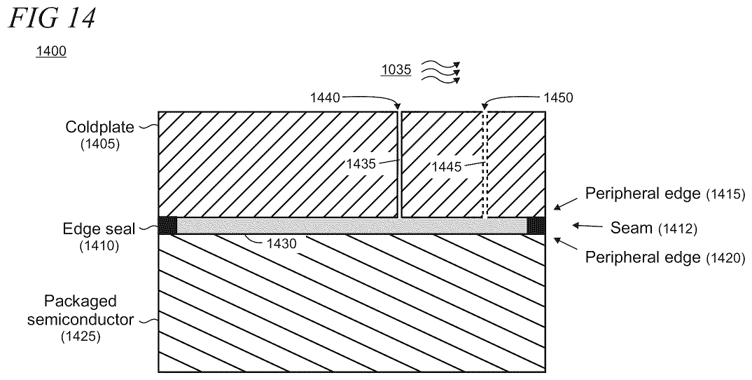

FIG. 14 is schematic side view of an illustrative semiconductor assembly 1400 in which a coldplate 1405 is arranged with an edge seal 1410 located around a perimeter seam 1412 between respective peripheral edges 1415 and 1420 of the coldplate and a packaged semiconductor 1425. The seal prevents pump-out and leakage of the TIM 1430 from the semiconductor assembly. The coldplate is further arranged to include a capillary tube 1435 with an opening 1440 exposed to the surrounding environment 1035. An additional diversely-located capillary tube 1445 with opening 1450 is optionally utilized in this illustrative embodiment as indicated by the dashed lines.

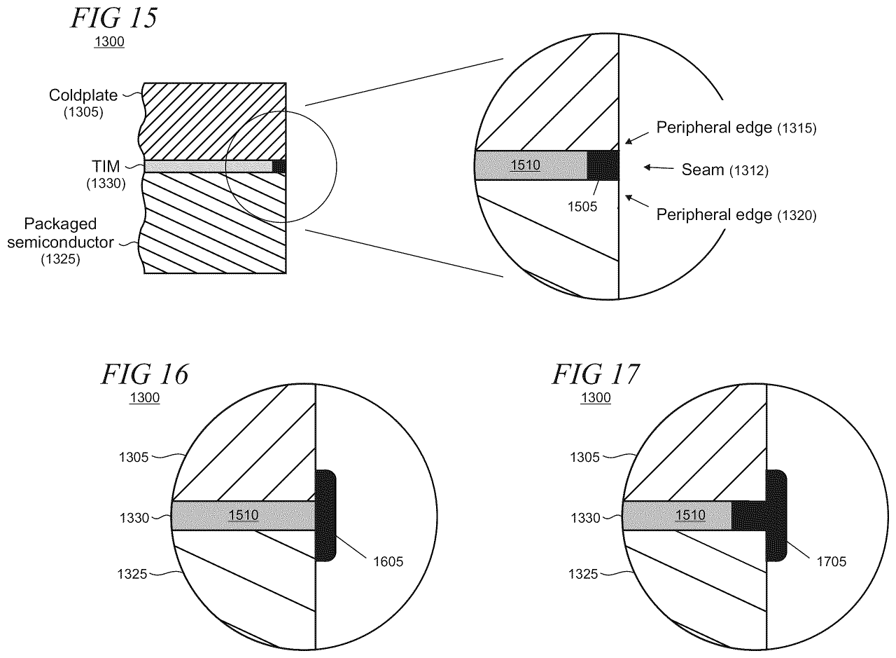

FIGS. 15-21 are schematic side views of different illustrative seals that may be used singly or in combination with the illustrative semiconductor assembly embodiments. FIG. 15 shows an illustrative edge seal 1505 that holds the TIM 1330 within an internal volume 1510 formed between the coldplate 1305 and packaged semiconductor 1325. The seal is internally captured by the coldplate and semiconductor around the perimeter seam 1312 at the respective peripheral edges 1315 and 1320, as shown. When positioned in place between the opposing mating surfaces of the rigid coldplate and packaged semiconductor, the seal imparts fluid-sealant properties to the semiconductor assembly 1300.

The seal 1505 is configurable as an elastically or plastically deformable gasket that is capable of withstanding the expected operating temperatures of the semiconductor assembly 1300 without degradation within some predetermined operating lifespan. Various materials are usable for the seals described herein including those that are pliable, compliant, or otherwise malleable, and which are pressure-rated to provide a suitable seal to prevent TIM leakage or extrusion from pump-out. The seal is configurable using a single material or using composite materials that may include stiffeners or reinforcements. For example, the seal may include a rubberized exterior (e.g., neoprene, silicone, and the like) with rigid internal reinforcements such as metallic or polymeric plates, fibers, components, fillers, or the like. Alternatively, the seal is configurable using viscous sealants that are non-curing, partially-curing, or fully-curing, depending on the needs of a particular application such as rework-ability in manufacturing. Another alternative seal configuration comprises preferentially cooling the edges of the semiconductor assembly with the coldplate 1305 to solidify the TIM along the cooled edges to thereby form a seal. In some applications, combinations of seal types and techniques may be utilized.

FIG. 16 shows an illustrative seal 1605 that is disposed substantially around the external perimeter of the seam of the coldplate 1305 and packaged semiconductor 1325, but is not captured internally between opposing surfaces of the coldplate and semiconductor as with seal 1505. Utilization of seal 1605 may provide some manufacturing advantages by simplifying assembly of the semiconductor assembly. FIG. 17 shows an illustrative seal 1705 that combines external and internal sealing mechanisms. The seal 1705 provides additional sealing area compared to seals 1505 and 1605 and includes non-planar sealing surfaces that may increase pressure rating in some cases.

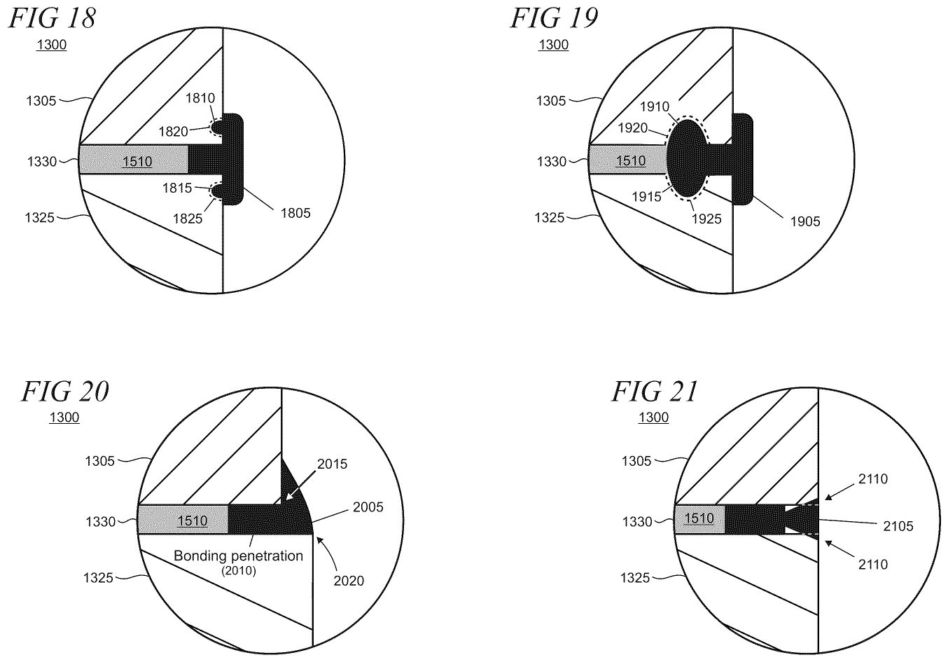

FIG. 18 shows an illustrative seal 1805 that includes ribs 1810 and 1815 that interface with respective rib-receiving features 1820 and 1825 located on external surfaces of the coldplate 1305 and packaged semiconductor 1325. The ribs may facilitate proper location of the seal during manufacturing of the semiconductor assembly 1300 and may also provide for increased sealing surface area and pressure-resistance. FIG. 19 shows an illustrative seal 1905 that includes ribs 1910 and 1915 that interface with respective internally-disposed rib-receiving features 1920 and 1925. As with seal 1805, seal 1905 may facilitate proper location of the seal during manufacturing of the semiconductor assembly 1300 and also provide for an increase in sealing surface area and pressure-resistance.

FIG. 20 shows an illustrative seal 2005 that is implemented using edge bonding with an adhesive such as epoxy that is dispensed using a hollow needle or other suitable application system around the external perimeter of the seam of the coldplate 1305 and packaged semiconductor 1325. The edge bonding seal 2005 typically penetrates the gap between the opposing surfaces of the coldplate and semiconductor, as indicated by reference numeral 2010, to enhance sealing, but penetration of the adhesive under the coldplate is not required in all cases. The dispensing of the edge bonding may be similar to that employed with conventional semiconductor packaging when bonding the semiconductor to the PCB, as discussed above.

As shown, the respective peripheral edges 2015 and 2020 of the coldplate 1305 and packaged semiconductor 1325 are laterally offset to provide additional bonding area for the adhesive and facilitate penetration of the material into the gap between the components. The offset edge features may enhance mechanical bonding between the coldplate and semiconductor and facilitate a strong seal of the TIM 1330 within the internal volume 1510.

FIG. 21 shows an illustrative knife-edge seal 2105 that is captured in the internal volume 1510 between the opposing surfaces of the coldplate 1305 and packaged semiconductor 1325. The knife-edge seal is a metal-to-metal seal with a specific geometry designed to concentrate the applied assembly force from the coldplate attachment to the semiconductor into a relatively small width on the seal 2105.

The knife-edge portions 2110 of the seal 2105 are configured as a harder material than the corresponding mating surfaces which can include an intermediate gasket (not shown) made of softer material such as copper or the surfaces of the coldplate and semiconductor themselves. When the coldplate 1305 is assembled to the semiconductor 1325, the softer material is extruded out from the knife-edge grooves to fill and seal the seam between the mating components.

Various exemplary embodiments of the present pump-out resistant coldplate are now presented by way of illustration and not as an exhaustive list of all embodiments. An example includes a semiconductor assembly, comprising: a semiconductor including a heat-producing die, the semiconductor having a broad area surface through which heat is conducted from the die; a heat exchanger having a mating broad area surface that interfaces with the semiconductor; thermal interface material (TIM) disposed in a TIM-receiving volume formed between the respective broad area surfaces of the semiconductor and the heat exchanger; and a seal disposed around an outer perimeter of the receiving volume formed between the semiconductor and the heat exchanger that traps the TIM within the TIM-receiving volume.

In another example, the seal comprises one of gasket, O-ring, knife-edge gasket, or edgebond adhesive. In another example, the TIM comprises one of phase change material, thermal grease, thermal paste, thermal putty, thermal gel, graphite-based material, silicone-based material, or metal-based material. In another example, the semiconductor assembly further includes a seal-receiving feature disposed in one or more of the heat exchanger or semiconductor, the seal-receiving feature comprising one of slot, groove, lip, offset edge, or surface texture. In another example, the heat exchanger comprises one of heatsink or coldplate. In another example, the coldplate is liquid-cooled. In another example, the semiconductor includes an integrated heat spreader providing the broad area surface through which heat is conducted from the die.

A further example includes a semiconductor assembly, comprising: a semiconductor including a heat-producing die, the semiconductor having a broad area surface through which heat is conducted from the die; a heat exchanger disposed on the semiconductor, the heat exchanger having a broad area surface interfacing with the broad area surface of the semiconductor; thermal interface material (TIM) disposed as a layer in an interstitial air gap between mating broad area surfaces of the semiconductor and heat exchanger, the TIM being flowable in the interstitial air gap; and a capillary tube disposed in the heat exchanger extending from the broad area surface of the heat exchanger to an opening in the heat exchanger that is exposed to an atmosphere surrounding the semiconductor assembly, wherein the capillary tube provides a reservoir into which the TIM is displaced and from which the TIM is recoverable as the TIM flows in the interstitial air gap.

In another example, the TIM comprises a viscous liquid material and the capillary tube has a radius dimension between a central axis of the tube and a sidewall of the tube, the radius dimension being selected to maintain a target pressure differential across a vapor-liquid interface between the TIM and air in the capillary tube from the atmosphere surrounding the semiconductor assembly, wherein the pressure differential is determined by the radius dimension, surface tension of the liquid TIM in the capillary tube, and a contact angle between the liquid TIM and the sidewall. In another example, the broad area surface of the semiconductor comprises a lid, wherein the lid has flexure motion relative to the heat exchanger as the semiconductor is operated. In another example, the capillary tube is axially located in line with a point of local maximum excursion of the lid. In another example, the capillary tube is axially located in line with a point of local maximum temperature of the lid. In another example, the capillary tube is axially located in line with a point of local maximum pressure of the TIM. In another example, the capillary tube has an aspect ratio that maximizes resistance to air intrusion into the interstitial air gap through the opening in the heat exchanger exposed to the surrounding atmosphere.

A further example includes a semiconductor assembly, comprising: a semiconductor including a heat-producing die, the semiconductor having a broad area surface through which heat is conducted from the die, wherein the broad area surface deforms with a membrane-like pumping motion as the semiconductor undergoes cyclical thermal loading through operations of the heat-producing die; a heat exchanger having a broad area surface interfacing with the broad area surface of the semiconductor; thermal interface material (TIM) filling a gap between mating broad area surfaces of the semiconductor and heat exchanger, the TIM being flowable with the membrane-like pumping motion of the semiconductor; a seal around a seam between the semiconductor and the heat exchanger that limits excursion of the TIM from the gap as the broad area surface of the semiconductor deforms with the membrane-like pumping motion; and a capillary tube disposed in the heat exchanger extending from the broad area surface of the heat exchanger to an opening in the heat exchanger that is exposed to an atmosphere surrounding the semiconductor assembly, wherein the capillary tube provides a volume to receive the flowable TIM and wherein the TIM is restorable from the capillary tube.

In another example, the broad area surface of the semiconductor is incorporated into a lid or integrated heat spreader. In another example, the TIM is cyclically flowable and restorable from the capillary tube with cyclical thermal loading of the semiconductor. In another example, the semiconductor assembly further comprises a plurality of capillary tubes distributed in the heat exchanger. In another example, the seal comprises a reworkable edgebond adhesive. In another example, the seal around the seam is airtight.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A semiconductor assembly, comprising:
a semiconductor including a heat-producing die, the semiconductor having a broad area surface through which heat is conducted from the die;
a heat exchanger having a mating broad area surface that interfaces with the semiconductor;
thermal interface material (TIM) disposed in a TIM-receiving volume formed between the respective broad area surfaces of the semiconductor and the heat exchanger; and
a seal disposed around an outer perimeter of the receiving volume formed between the semiconductor and the heat exchanger that traps the TIM within the TIM-receiving volume.

2. The semiconductor assembly of claim 1 in which the seal comprises one of gasket, O-ring, knife-edge gasket, or edgebond adhesive.

3. The semiconductor assembly of claim 1 in which the TIM comprises one of phase change material, thermal grease, thermal paste, thermal putty, thermal gel, graphite-based material, silicone-based material, or metal-based material.

4. The semiconductor assembly of claim 1 further including a seal-receiving feature disposed in one or more of the heat exchanger or semiconductor, the seal-receiving feature comprising one of slot, groove, lip, offset edge, or surface texture.

5. The semiconductor assembly of claim 1 in which the heat exchanger comprises one of heatsink or coldplate.

6. The semiconductor assembly of claim 5 in which the coldplate is liquid-cooled.

7. The semiconductor assembly of claim 1 in which the semiconductor includes an integrated heat spreader providing the broad area surface through which heat is conducted from the die.

8. A semiconductor assembly, comprising:
a semiconductor including a heat-producing die, the semiconductor having a broad area surface through which heat is conducted from the die;
a heat exchanger disposed on the semiconductor, the heat exchanger having a broad area surface interfacing with the broad area surface of the semiconductor;
thermal interface material (TIM) disposed as a layer in an interstitial air gap between mating broad area surfaces of the semiconductor and heat exchanger, the TIM being flowable in the interstitial air gap; and
a capillary tube disposed in the heat exchanger extending from the broad area surface of the heat exchanger to an opening in the heat exchanger that is exposed to an atmosphere surrounding the semiconductor assembly, wherein the capillary tube provides a reservoir into which the TIM is displaced and from which the TIM is recoverable as the TIM flows in the interstitial air gap.

9. The semiconductor assembly of claim 8 in which the TIM comprises a viscous liquid material and the capillary tube has a radius dimension between a central axis of the tube and a sidewall of the tube, the radius dimension being selected to maintain a target pressure differential across a vapor-liquid interface between the TIM and air in the capillary tube from the atmosphere surrounding the semiconductor assembly, wherein the pressure differential is determined by the radius dimension, surface tension of the liquid TIM in the capillary tube, and a contact angle between the liquid TIM and the sidewall.

10. The semiconductor assembly of claim 8 in which the broad area surface of the semiconductor comprises a lid, wherein the lid has flexure motion relative to the heat exchanger as the semiconductor is operated.

11. The semiconductor assembly of claim 10 in which the capillary tube is axially located in line with a point of local maximum excursion of the lid.

12. The semiconductor assembly of claim 10 in which the capillary tube is axially located in line with a point of local maximum temperature of the lid.

13. The semiconductor assembly of claim 8 in which the capillary tube is axially located in line with a point of local maximum pressure of the TIM.

14. The semiconductor assembly of claim 8 in which the capillary tube has an aspect ratio that maximizes resistance to air intrusion into the interstitial air gap through the opening in the heat exchanger exposed to the surrounding atmosphere.

15. A semiconductor assembly, comprising:
a semiconductor including a heat-producing die, the semiconductor having a broad area surface through which heat is conducted from the die, wherein the broad area surface deforms with a membrane-like pumping motion as the semiconductor undergoes cyclical thermal loading through operations of the heat-producing die;
a heat exchanger having a broad area surface interfacing with the broad area surface of the semiconductor;
thermal interface material (TIM) filling a gap between mating broad area surfaces of the semiconductor and heat exchanger, the TIM being flowable with the membrane-like pumping motion of the semiconductor;
a seal around a seam between the semiconductor and the heat exchanger that limits excursion of the TIM from the gap as the broad area surface of the semiconductor deforms with the membrane-like pumping motion; and
a capillary tube disposed in the heat exchanger extending from the broad area surface of the heat exchanger to an opening in the heat exchanger that is exposed to an atmosphere surrounding the semiconductor assembly, wherein the capillary tube provides a volume to receive the flowable TIM and wherein the TIM is restorable from the capillary tube.

16. The semiconductor assembly of claim 15 in which the broad area surface of the semiconductor is incorporated into a lid or integrated heat spreader.

17. The semiconductor assembly of claim 15 in which the TIM is cyclically flowable and restorable from the capillary tube with cyclical thermal loading of the semiconductor.

18. The semiconductor assembly of claim 15 further comprising a plurality of capillary tubes distributed in the heat exchanger.

19. The semiconductor assembly of claim 15 in which the seal comprises a reworkable edgebond adhesive.

20. The semiconductor assembly of claim 15 in which the seal around the seam is airtight.
